(19) United States
(12) Patent Application Publication
(10) Pub. No.: US 2017/0285457 A1
(43) Pub. Date: Oct. 5, 2017

(54) LASER ABLATION TOOLING VIA SPARSE PATTERNED MASKS

(71) Applicant: 3M INNOVATIVE PROPERTIES COMPANY, St. Paul, MN (US)

(72) Inventor: Thomas R. Corrigan, St. Paul, MN (US)

(21) Appl. No.: 15/628,748

(22) Filed: Jun. 21, 2017

Related U.S. Application Data
(63) Continuation of application No. 12/275,669, filed on Nov. 21, 2008, now abandoned.

(51) Int. Cl. G03F 1/20; G03F 1/70; B23K 26/066; G03F 7/24

(52) U.S. Cl. CPC G03F 1/20; G03F 7/24; G03F 1/70; Y10T 428/24802; B23K 26/066

(57) ABSTRACT

A sparse patterned mask for use in a laser ablation process to image a substrate. The mask has a plurality of apertures for transmission of light and non-transmissive areas around the apertures. The apertures individually form a portion of a complete pattern, and a plurality of apertures from one or more masks together form the complete pattern when the masks are imaged. Making a mask sparse provides for a path to remove debris from the substrate during the laser ablation process. Multiple interlaced sparse repeating patterns can create a more complex pattern with repeat distances larger than the individual patterns.

### BACKGROUND

Excimer lasers have been used to ablate patterns into polymer sheets using imaging systems. Most commonly, these systems have been used to modify products, primarily to cut holes for ink jet nozzles or printed circuit boards. This modification is performed by overlaying a series of identical shapes with the imaging system. The mask of constant shapes and a polymer substrate can be held in one place while a number of pulses from the laser are focused on the top surface of the substrate. The number of pulses is directly related to the hole depth. The fluence (or energy density) of the laser beam is directly related to the cutting speed, or microns of depth cut per pulse (typically 0.1-1 micron for each pulse).

Moreover, 3D structures can be created by ablating with an array of different discrete shapes. For instance, if a large hole is ablated into a substrate surface, and then smaller and smaller holes are subsequently ablated, a lens like shape can be made. Ablating with a sequence of different shaped openings in a single mask is known in the art. The concept of creating that mask by cutting a model (such as a spherical lens) into a series of cross sections at evenly distributed depths is also known.

However, the repeating structures made with these laser ablation systems tend to create moiré when used to make a film for a display. Moiré is a visual defect created when two repeating patterns are combined. Most current displays utilize a constant pitch, repeating array of pixels. Any materials that are added to that display can create a moiré pattern defect.

### SUMMARY

A sparse patterned mask, consistent with the present invention, can be used in a laser ablation process to image a substrate. The mask has one or more plurality of apertures for transmission of light and non-transmissive areas around the apertures. The apertures individually form a portion of a complete pattern, and the non-transmissive areas exist on the mask in regions between the first apertures that correspond to non-imaged regions on the substrate that are subsequently imaged by second apertures on the same or a different mask to create the complete pattern.

A mask is a discrete region of apertures that can be imaged at a single time by the laser illumination system. More than one mask may exist on a single glass plate if the plate is much larger than the field of view of the illumination system. Changing from one mask to another may include moving the glass plate to bring another region into the laser illumination field of view.

A method for laser imaging a substrate, consistent with the present invention, uses a sparse patterned mask. The method includes imaging the substrate through a first mask having apertures for transmission of light and non-transmissive areas around the apertures, and subsequently imaging the substrate through one or more second masks each having apertures for transmission of light and non-transmissive areas around the apertures. The apertures in the first mask form a first portion of a complete pattern of features, and the apertures in the one or more second masks form a second portion of the complete pattern of features. The first mask and the one or more second masks together form the complete pattern of features when the first mask and the one or more second masks are individually imaged.

Another method for laser imaging a substrate, consistent with the present invention, also uses a sparse patterned mask. The method includes imaging the substrate such that a region on the substrate is imaged by the first apertures in the mask for transmission of light and subsequently imaging the region of the substrate through one or more second apertures in the mask. Non-transmissive areas surround the first apertures and the one or more second apertures. The image of the first apertures in the mask in combination with the one or more images of second apertures form a complete pattern of features. The features may be created from only the first apertures, only the second apertures, or a combination of first and second apertures.

A microreplicated article, consistent with the present invention, has two or more repeating arrays of discrete features. Each of the arrays of features forms a constituent pattern as part of a complete pattern. The arrays of features are interlaced to create the complete pattern of the features that repeats over a distance greater than a repeat distance of any of the constituent patterns.

### BRIEF DESCRIPTION OF THE DRAWINGS

The accompanying drawings are incorporated in and constitute a part of this specification and, together with the description, explain the advantages and principles of the invention. In the drawings,

FIG. 1 is a diagram of a system for performing laser ablation on a flat substrate;

FIG. 2 is a diagram of a system for performing laser ablation on a cylindrical substrate;

FIGS. 3a-3c are diagrams illustrating the creation of three interlaced sparse patterns on a cylindrical tool;

FIG. 4 is a diagram of a first type of repeating pattern;

FIG. 5 is a diagram of a second type of repeating pattern;

FIG. 6 is a diagram of a portion of a complete pattern having hexagonal structures;

FIG. 7 is a diagram of a portion of a complete pattern having ring-like structures;

FIG. 8 is a diagram illustrating a sparse mask that could produce the pattern in FIG. 6;

FIG. 9 is a diagram illustrating a sparse mask that could produce the pattern in FIG. 7;

FIG. 10 is a diagram showing a portion of a one-third sparse hexagonal packed pattern;

FIG. 11 is a diagram showing a portion of a second one-third sparse hexagonally packed pattern interlaced with the pattern of FIG. 10;

FIG. 12 is a diagram showing a portion of a third one-third sparse hexagonally packed pattern interlaced with the two patterns of FIG. 11;

FIG. 13 is a diagram illustrating a sparse mask that could produce the sparse pattern of FIG. 10; and

FIGS. 14 and 14a are diagrams illustrating a cylindrical substrate that has been threadcut on a portion of its surface with a sparse pattern. A detailed view of the pattern is also shown.

### DETAILED DESCRIPTION

Embodiments of the present invention relate to techniques for designing and using a mask based imaging system to produce patterns via laser ablation or lithography based systems. The techniques involve dividing a pattern on a mask to make that pattern sparse. In a first embodiment, a regular pattern to be used for imaging can be divided into smaller subregions with empty space added between the subregions. The original pattern is then reassembled during the raster of the imaging process. In a second embodiment, the complete pattern is obtained by imaging individual masks with sparse patterns and interlacing those patterns to create a new pattern. A number of masks with sparse patterns that have different repeating distances may be used. These repeating distances are ideally prime numbers such that the overall pattern repeats over a distance much larger than the individual mask image size. This technique can be used, for example, to make a pattern that is difficult to identify and less likely to produce moiré in combination with another pattern or itself.

The empty space in the subpatterns is beneficial during an ablation process. In particular, the empty space in the masks allows the laser ablation plume (an expanding wave of plasma that “explodes” from the surface anywhere it is hit with radiation) to expand more freely. The empty space also reduces two significant problems routinely encountered in laser ablation: macro scale defects (lines) corresponding to the step over distance on a laser ablation tool are greatly reduced; and the nature of the debris that is left on the surface of the tool is changed such that it can be more easily removed.

### Laser Ablation Systems

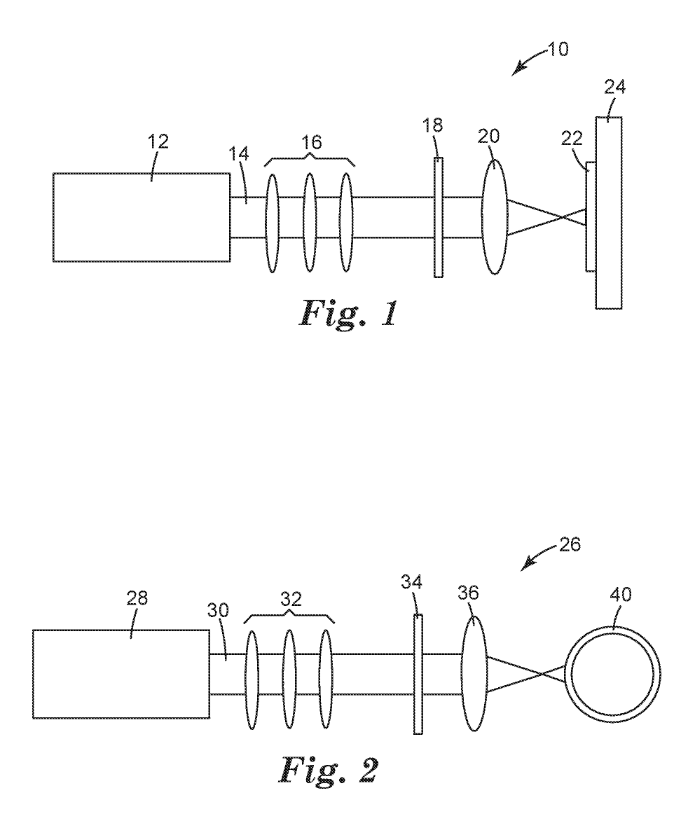

FIG. 1 is a diagram of a system 10 for performing laser ablation on a substantially flat substrate. System 10 includes a laser 12 providing a laser beam 14, optics 16, a mask 18, imaging optics 20, and a substrate 22 on a stage 24. Mask 18 patterns laser beam 14 and imaging optics 20 focus the patterned beam onto substrate 22 in order to ablate material on the substrate. Stage 24 is typically implemented with an x-y-z stage that provides for movement of the substrate, via stage 24, in mutually orthogonal x- and y-directions that are both also orthogonal to laser beam 14, and a z-direction parallel to laser beam 14. Therefore, movement in the x- and y-directions permits ablation across substrate 22, and movement in the z-direction can assist in focusing the image of the mask onto a surface of substrate 22.

FIG. 2 is a diagram of a system 26 for performing laser ablation on a substantially cylindrical substrate. System 26 includes a laser 28 providing a laser beam 30, optics 32, a mask 34, imaging optics 36, and a cylindrical substrate 40. Mask 34 patterns laser beam 30 and imaging optics 36 focus the patterned beam onto substrate 40 in order to ablate material on the substrate. The substrate 40 is mounted for rotational movement in order to ablate material around substrate 40 and is also mounted for movement in a direction parallel to the axis of substrate 40 in order to ablate material across substrate 40. The substrate can additionally be moved parallel and orthogonal to the beam 30 to keep the image of the mask focused on the substrate surface.

The masks 18 and 34, or other masks, have apertures to allow transmission of laser light and non-transmissive areas around the apertures to substantially block the laser light. One example of a mask includes a metal layer on glass with a photoresist in order to make the apertures (pattern) via lithography. The mask may have varying sizes and shapes of apertures. For example, a mask can have round apertures of varying diameters, and the same position on the substrate can be laser ablated with the varying diameter apertures to cut a hemispherical structure into the substrate.

Substrates 22 and 40 can be implemented with any material capable of being machined using laser ablation, typically a polymeric material. In the case of cylindrical substrate 40, it can be implemented with a polymeric material coated over a metal roll. Examples of substrate materials are described in U.S. Patent Applications Publication Nos. 2007/0235902A1 and 2007/0231541A1, both of which are incorporated herein by reference as if fully set forth.

Once the substrates have been machined to create microstructured articles, they can be used as a tool to create other microreplicated articles, such as optical films. Examples of structures within such optical films and methods for creating the films are provided in U.S. Patent Application Publication No. 2010/0128351, which is incorporated herein by reference as if fully set forth.

The microreplicated articles can have features created by a laser imaging process using sparse masks as described below. The term “feature” means a discrete structure within a cell on a substrate, including both a shape and position of the structure within the cell. The discrete structures are typically separated from one another; however, discrete structures also includes structures in contact at the interface of two or more cells.

Laser machining of flat and cylindrical substrates is more fully described in U.S. Pat. Nos. 6,285,001 and 7,985,941, both of which are incorporated herein by reference as if fully set forth.

Sparse Masks for Regular Patterns with a Single Mask

A mask to produce a repeating pattern on a laser ablation system 10, for example, can be made sparse, using a sparse mask, such that it has empty spaces in one-half, two-thirds, or three-fourths of the pattern, or in other ratios. Then one, two, or three or more passes of that mask image or others across the substrate are required respectively to fill in the gaps. If the distance between repeating structures on the one, two, or three (or more) passes are significantly different (preferably prime numbers) then the distance between true repeats of the structure can be many times larger than the mask image size, exceeding several centimeters in practice. The structure can have randomly shaped or arranged features within the cells of the repeating structure. The distance between repeats on a single mask is generally less than 5 millimeters across, more commonly 1 mm or less.

Table 1 illustrates a non-sparse laser ablation mask that has a single row of a repeating pattern (feature A), where feature A consists of one or more sub features, or distinct regions, that block or transmit light on the mask.

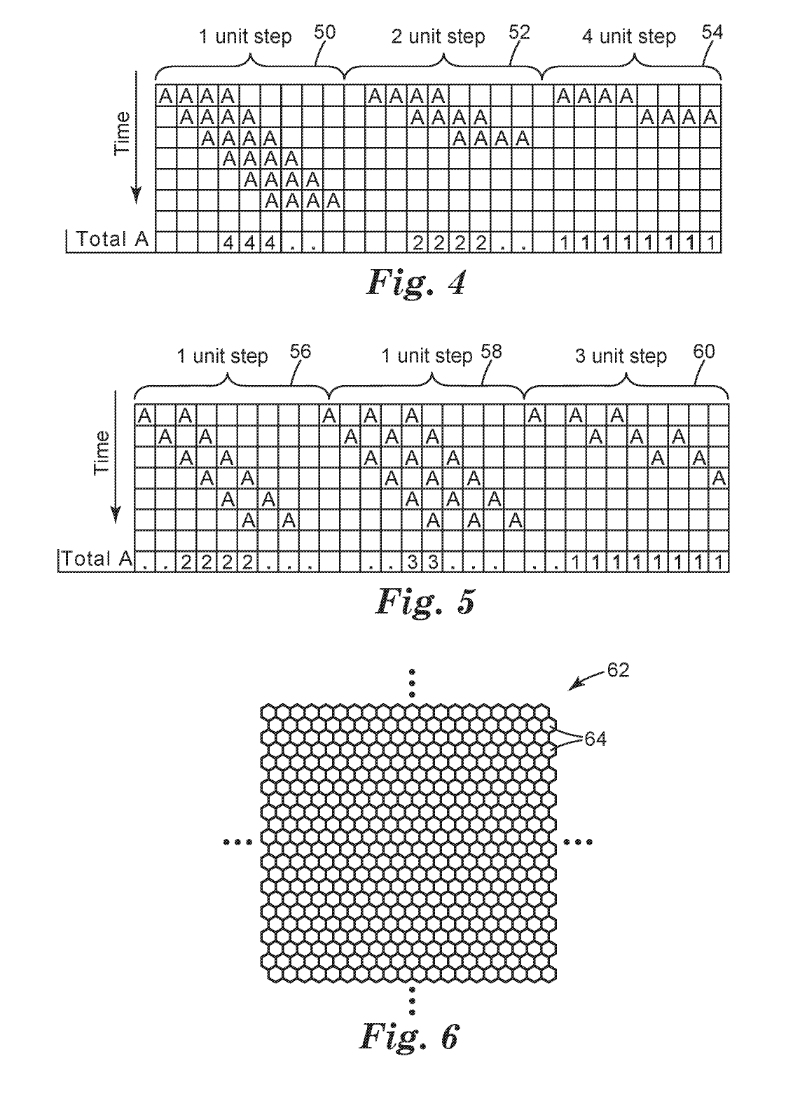

This pattern can then be used during rastering, as shown in FIG. 4, with steps of 1 unit (50), 2 units (52), or 4 units (54), overlaying respectively 4, 2, or 1 images of feature A per pass. In a laser ablation system, many images of the same feature must often be overlaid at each location to cut the feature to the proper depth. Rastering involves imaging the mask during or after moving the substrate, as described in U.S. Pat. No. 6,285,001.

Two possible sparse versions of the same pattern are shown in Table 2.

These patterns can then be used during rastering, as shown in FIG. 5, with steps of size 1 unit (56), and 1 unit (58) or 3 units (60), resulting in the imaging of 2, 3, or 1 overlaid images of feature A per pass respectively.

There can be constraints on the arrangement of sparse patterns. For most applications, it is desirable to have a uniform application of repeating features, for example the same number of pattern A in each column as shown in FIGS. 4 and 5. For such applications, any type of sparse pattern can be used if it is rastered at 1 basic unit step size. In addition, if there are an odd number (N) of repeats with equal sized empty spaces between them (creating a total mask width of 2N), then the pattern can be rastered in steps of N units, as shown with the 3 unit step in FIG. 5 (60). If a non-uniform distribution of features is desired, then these constraints can be reduced.

Any type of pattern can be divided to become sparse. However, there are two types of patterns that benefit most from being made sparse. One type includes dense patterns; or applications that require the ablation of material over almost the entire surface of the substrate. These applications require masks that transmit most of the light on at least a portion of the mask. For example, a pattern of continuous grooves would require the removal of most of the top surface where the tops of the grooves are just starting to form. Discrete shapes that touch each other also require a large percentage of material removal from at least part of the mask image. These dense patterns can be difficult to laser ablate since little area is left for the ablated debris to escape from the substrate, often resulting in macro-scale defects and tenacious debris. In addition, dense patterns create more auditory noise during ablation, and they also causes more wear on the imaging optics.

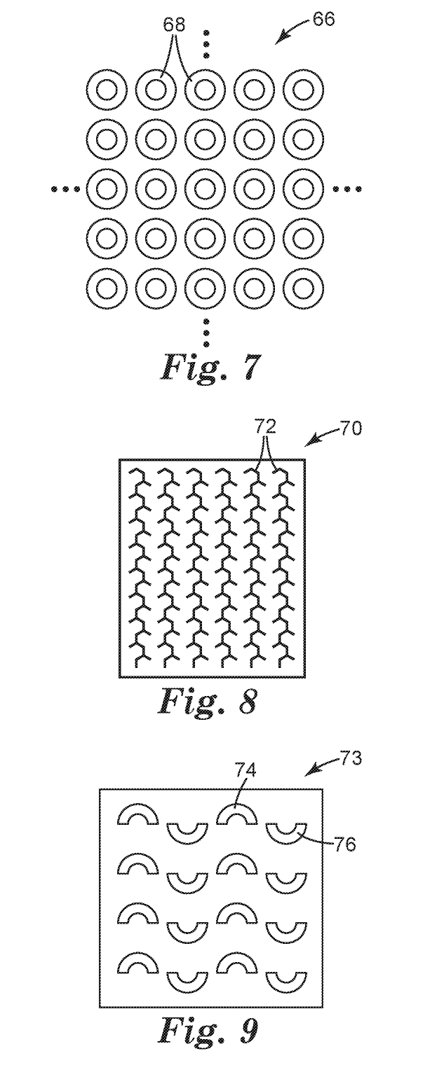

A second type of pattern that benefits from sparseness is a confined pattern. Confined patterns have a non-imaged region completely surrounded by an imaged area. Experience has shown that these confined regions can restrict the ablation plume. When a pattern has an “escape path” for the ablation plume they perform much better in terms of debris tenacity and macro-scale defects. To provide for such an “escape path,” the pattern is made sparse such that there are no non-ablated regions that are completely enclosed by ablated regions. Confined patterns can be continuous, such as the generic hexagonal pattern 62 with a continuous array of hexagonal features 64 shown in FIG. 6. Confined patterns can also be discrete structures such as pattern 66 having an array of ring-like shapes 68, as shown in FIG. 7.

Both of these patterns 62 and 66 can be made with sparse masks to provide an “escape path” for the ablation plume, as shown in FIGS. 8 and 9. As shown in FIG. 8, pattern 62 can be made from a sparse mask 70 that has apertures 72 that individually form only a portion of the hexagonal pattern and together with other copies form the continuous hexagonal pattern of features. Pattern 62 is an example of a constituent pattern as part of the complete hexagonal pattern of features. As shown in FIG. 9, pattern 66 can be made from a sparse mask 73 by using apertures 74 and 76 that individually form only portions of the ring-like pattern and together form the complete pattern of ring-like features. Pattern 66 is an example of a constituent pattern as part of the complete square pattern of features. The sparse patterned masks are then imaged with a laser ablation process onto different regions of a substrate such that the complete pattern is ablated on the substrate using a step and repeat, or rastering, process.

Sparse Masks for Complex Patterns with Multiple Masks

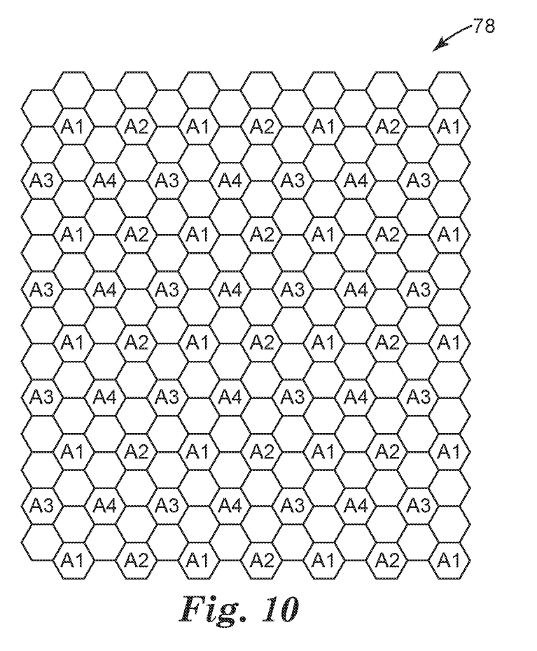

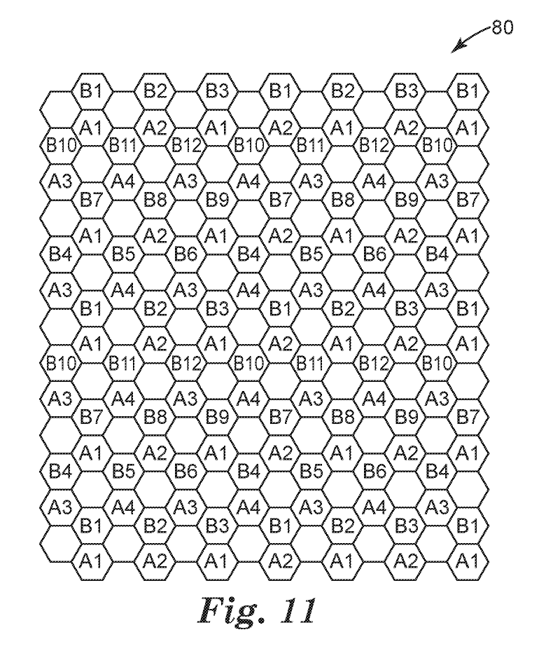

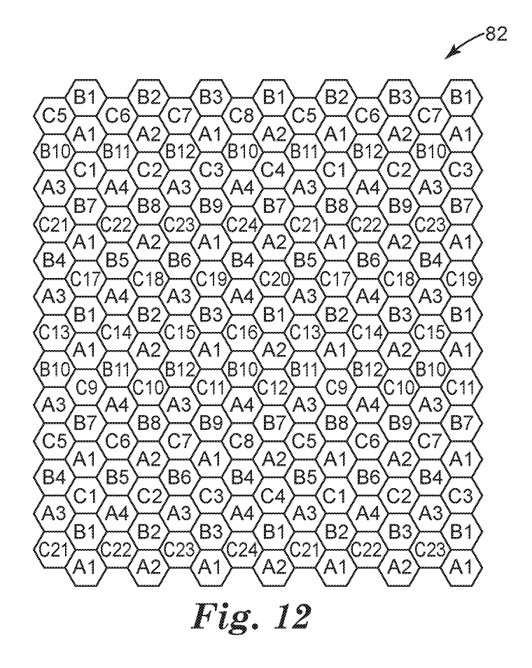

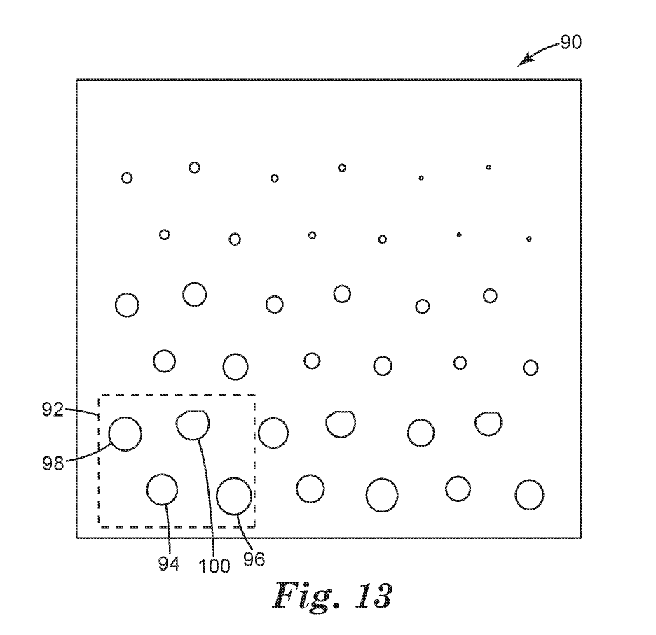

Multiple sparse masks can be interlaced to create a more complex pattern than a single mask can achieve. For example, if a hexagonal array of shapes (possibly to make lenses) is desired, then three one-third sparse masks can be employed. After a first pass with mask A, such as the one shown in FIG. 13, a repeating pattern 78 can be produced as shown in FIG. 10. This pattern 78 shows four different features (A1-A4) that repeat in a 2×1 pattern. The features are created by the superposition of multiple cross sections of the desired features. For example, region 92 in FIG. 13 contains one aperture for the largest cross section of each of four features, A1 (94), A2 (96), A3 (98) and A4 (100). The size of each of these axisymmetric features (i.e., lenses) and their position within their hexagonal cell are slightly different in the mask of FIG. 13. A single pass with mask 90 would superimpose the nine regions shown in FIG. 13 to produce the array of repeating features shown in pattern 78. A pass with a mask B would result in the combined pattern 80 shown in FIG. 11. Mask B is designed to produce a 3×2 repeating pattern of features (B1-B12). Again, each of the twelve features (B1-B12) can be slightly different in size and position relative to the hexagonal array. A final pass with a mask C would produce the pattern 82 shown in FIG. 12. Mask C is designed to produce features that repeat in a 4×3 pattern (C1-C24). All twenty-four of the features (C1-C24) can have a random position within the hexagonal cell and a random size.

When the combined pattern 82 is complete, it will appear to be random, but will have a repeat on the order of the hexagon cell size multiplied by the least common factor of the three repeats. In this case that would require only 12 steps in one direction and 6 steps in the other direction. If the nominal feature pitch (or hexagonal cell spacing) was 100 microns, then the pattern would repeat about every 2.08 mm in one direction and 0.60 mm in the other.

Another scenario for a hexagonal pattern includes repeating lenses that are about 10 microns in diameter. If three masks were again made, but using prime numbers of repeats, such as 37×17, 19×41, and 43×23 repeats, then the number of repeats between a full repeat of the pattern would be 30,229×16,031. This corresponds to about 524 mm (20.6 inches) in a horizontal direction and 481 mm (18.9 inches) in a vertical direction between repeats.

### Sparse Patterned Cylindrical Tool

There are at least two methods of applying sparse patterns to a cylindrical surface to create a pattern that repeats on a larger scale than any of the individual patterns. Applying a pattern to a cylindrical surface can use diamond turning techniques to machine the surface of a cylindrical tool; diamond turning is generally described in, for example, PCT Application Publication No. WO 00/48037, which is incorporated herein by reference as if fully set forth.

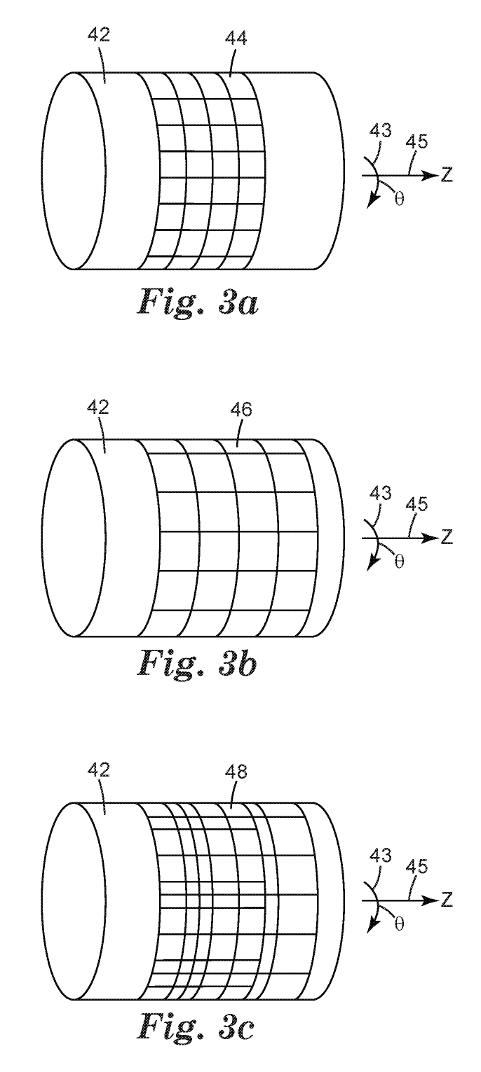

In a first method, each of the patterns is applied in discrete rows, as illustrated in FIGS. 3a-3c. In particular, FIG. 3a illustrates a first pattern 44 on a cylindrical substrate 42. FIG. 3b illustrates a second pattern 46 having a larger repeat distance in both the circumferential direction (43) and the axial direction (45) than pattern 44. FIG. 3c illustrates a pattern 48 representing pattern 44 interlaced with pattern 46. The patterns can interlace similar to the planar application of multiple patterns. The only additional constraint is that the total distance along the circumference (θ direction, 43) must be a multiple of the step distance in that direction for of all of the individual patterns. There is no constraint in the z-direction (45) for creating the interlaced pattern if the edges are discarded in production. The sparse interlaced pattern can be created using, for example, system 26 to machine the pattern into a substrate using laser ablation.

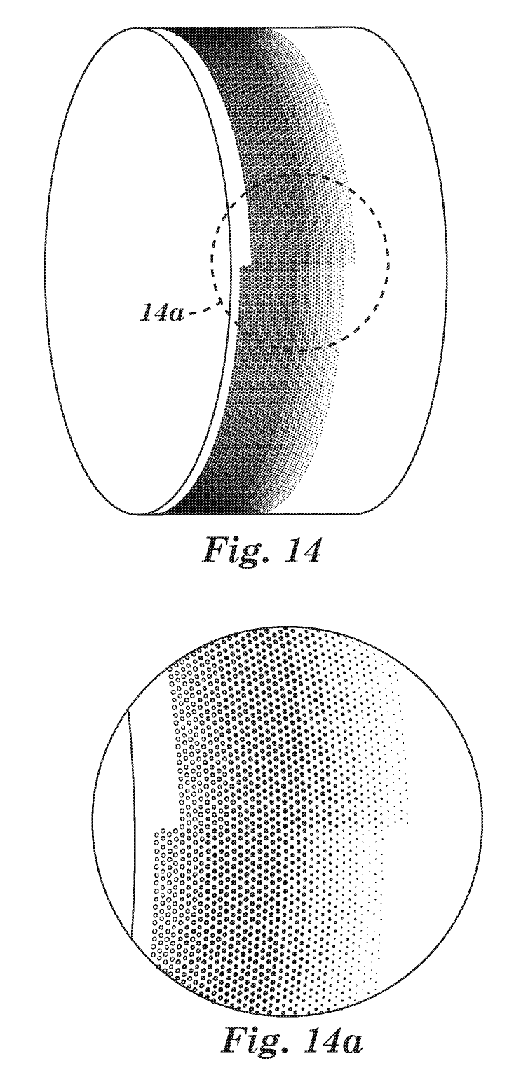

In a second method, multiple sparse patterns can be interlaced onto a cylindrical surface by thread cutting. Thread cutting can involve imaging the mask in steps along a helical path on the surface of a cylindrical substrate as shown in FIGS. 14 and 14a. The design of the mask and size of the steps and the pitch of the helix can be adjusted to create a pattern on the substrate surface that is an array of discrete or continuous features. Those features can be created in one or more passes of a properly designed sparse mask. A more complex pattern can also be created on the cylindrical substrate by the interlacing of multiple sparse patterns from properly designed sparse masks.

1. A method for laser imaging a substrate using two or more sparse patterned masks in order to form a complete pattern in a surface of the substrate, comprising:
imaging through the first mask a first pattern on the substrate, the first pattern leaving regions unexposed by the laser and having a first repeat distance; and
imaging through the second mask a second pattern on the substrate, the second pattern being different from the first pattern and leaving regions unexposed by the laser and having a second repeat distance, and the imaging comprises exposing the substrate with the second pattern such that laser is only exposed to regions not exposed by the first pattern on the substrate and interlacing the second pattern with the first pattern,
wherein the second pattern interlaced with the first pattern forms the complete pattern on the substrate, the complete pattern is different from both the first and second patterns, and the complete pattern has a greater repeat distance than the first and second repeat distances.

2. The method of claim 1, wherein there is some overlap on edges between the first pattern and the second pattern.

3. The method of claim 1, wherein the imaging steps comprise imaging a substantially flat substrate.

4. The method of claim 1, wherein the imaging steps comprise imaging a substantially cylindrical substrate.

5. The method of claim 1, wherein the imaging steps comprise imaging a polymeric material as the substrate.

6. The method of claim 1, wherein the complete pattern includes continuous features.

7. The method of claim 1, wherein the complete pattern includes discrete features.

8. A patterned cylindrical substrate having first features along a first helical path and second features along a second helical path with the first and second features interlaced to form the complete pattern, the substrate made by the method of claim 1.

9. A patterned flat substrate having first repeating features and second repeating features with the first and second features interlaced to form the complete pattern, the substrate made by the method of claim 1.

10. A method for laser imaging a substrate using two sparse patterned masks in order to form a complete pattern in a surface of the substrate, comprising:
imaging the substrate through a first sparse mask having apertures for transmission of light and non-transmissive areas around the apertures in order to form a first pattern composed of first features in the substrate, comprising:
imaging the first mask to form a portion of the first features;
moving the first mask to a different position relative to the substrate; and
repeating the imaging and moving steps to form the first pattern composed of the first features, wherein the first features comprise discontinuous repeating features on the substrate, and the first features collectively form the first pattern; and
imaging the substrate through the second mask to form a second pattern composed of second features interlaced with the first features in the first pattern, comprising:
imaging the second mask to form and interlace a portion of the second features in regions between the first features and the first pattern;
moving the second mask to a different position relative to the substrate; and
repeating the imaging and moving steps to form the second pattern composed of the second features,
wherein the second pattern is different from the first pattern, and the second pattern composed of the second features merges with the first pattern composed of the first features to form continuous repeating features comprising the complete pattern,
wherein the complete pattern is different from the first pattern and the second pattern, and the complete pattern repeats over a distance that is greater than a repeat distance of the first pattern and the second pattern.

11. The method of claim 10, wherein there is some overlap on edges between the first pattern and the second pattern.

12. The method of claim 10, wherein the imaging steps comprise imaging a substantially flat substrate.

13. The method of claim 10, wherein the imaging steps comprise imaging a substantially cylindrical substrate.

14. The method of claim 10, wherein the imaging steps comprise imaging a polymeric material as the substrate.

15. The method of claim 10, wherein the complete pattern includes continuous features.

16. The method of claim 10, wherein the complete pattern includes discrete features.
